(19) United States
(12) Patent Application Publication
(10) Pub. No.: US 2009/0325104 A1
(43) Pub. Date: Dec. 31, 2009

(54) PROCESS FOR MANUFACTURING SEMICONDUCTOR DEVICE

(75) Inventor: Fumiaki Hayashi, Kanagawa (JP)

Correspondence Address: YOUNG & THOMPSON, 209 Madison Street, Suite 500, Alexandria, VA, 22314, US

(73) Assignee: NEC Electronics Corporation, Kanagawa (JP)

(21) Appl. No.: 12/491,436

(22) Filed: Jun. 25, 2009

(30) Foreign Application Priority Data
Jun. 25, 2008 (JP) 2008-165724

(51) Int. Cl. G03F 7/20

(52) U.S. Cl. 430/312

(57) ABSTRACT

An operation for forming a trench after forming a via hole includes an operation for exposing a region for forming the via hole to light and an operation for exposing a region for forming the interconnect trench. More specifically, even if chemically amplified resist is buried in the via hole after the via hole is formed, then the region for forming of via hole is exposed to light again, so that the inside of the via hole is fully exposed to light. This allows removing the buried resist from the regions in via hole exposed to light, or namely the region and the region, with a developing solution, exposing at least a portion of the inner wall of the via hole to obtain the trench having a desired structure.

This application is based on Japanese patent application No. 2008-165,724, the content of which is incorporated hereinto by reference.

### BACKGROUND

1. Technical Field

The present invention relates to a method for manufacturing a semiconductor device.

2. Related Art

In recent advanced semiconductor devices, patterns of vias and interconnect trenches are formed by so-called via-first process, in which vias for providing coupling of the upper and the lower interconnects are, in particular, firstly formed in a dual damascene process.

When an advanced and finer interconnect configuration is formed by using the via-first process, a chemically amplified resist is used for a resist material. In such case, insufficient resolution of the chemically amplified resist is caused in the exposure or development of the interconnect pattern by external factors obstructing the chemically amplified resist such as, for example, diffusion of amines derived from the substrate or similar compounds into the chemically amplified resist, irrespective of a problem in optical resolution. This is called as a resist poisoning.

A generation of the resist poisoning may cause failure of processing the interlayer insulating film to a desired geometry, leading to a generation an interconnect failure such as electro migration (EM), stress induced void (SIV) and the like, so that a problem of degrading the reliability of the formed semiconductor chip.

Here, the condition of generating the resist poisoning will be described as follows. FIG. 7A to FIG. 8B are cross-sectional views, illustrating the condition of generating the resist poisoning when interconnects and vias are formed by a via-first process employing a chemically amplified resist.

First of all, a first etch stop film 402, a first interlayer insulating film 403, a second etch stop film 404, a second interlayer insulating film 405, and a third interlayer insulating film 406 are deposited on an underlying interconnect layer 401. Subsequently, a via hole 411 is formed in the third interlayer insulating film 406, the second interlayer insulating film 405, the second etch stop film 404 and the first interlayer insulating film 403 by known lithography technique and etching technique (FIG. 7A)

Subsequently, an anti-reflection film 407 is formed on the third interlayer insulating film 406 and the first etch stop film 402 (FIG. 7B). In this occasion, the via hole 411 is partially stuffed with the anti-reflection film 407.

Subsequently, a chemically amplified resist 408 is applied over the anti-reflection film 407 (FIG. 7C). In such case, the inside, the upper surface and the circumference of the via hole 411 are covered with the chemically amplified resist 408.

Then, an aperture-pattern 412, which is employed for forming an interconnect trench that is coupled to the via hole 411, is transferred to the chemically amplified resist 408, and then the resist is developed (FIG. 8A). Then, the anti-reflection film 407 is removed, and the third interlayer insulating film 406 and the second interlayer insulating film 405 are removed by an etching process (FIG. 8B).

In such case, as shown in FIG. 8A, the chemically amplified resist 408 over the inside, the upper surface and the circumference of the via hole 411 are sometimes not completely removed, being partially remained, because of the presence amines or nitrogen-contained material on the substrate, especially in dielectric layers. Therefore, in the circumference of the remained portions of the chemically amplified resist 408, a remained fence 414 of the third interlayer insulating film 406 and the second interlayer insulating film 405 is formed in the circumference and the upper surface of the via hole 411 as shown in FIG. 8B.

The remained fence 414 is not removed in the subsequent O₂ plasma ashing process and the stripping process with an organic stripping solution, remaining in the interconnect trench 413. This causes an interconnect failure such as an electro migration (EM), a stress induced void (SIV) and the like, reducing the reliability of the formed semiconductor device 400.

Such remained fence 414 is a photo-insensitive portion of the chemically amplified resist 408 caused by the resist poisoning effect, leading to partially remained resist. More specifically, amine or similar compound contained in a substrate or an interlayer insulating film at a very smaller amount is diffused in the via hole 411 created within the chemically amplified resist 408, and reacts with acid generated in the chemically amplified resist 408 during the exposure process to cause a neutralizing reaction, deteriorating the photo-sensibility of the chemically amplified resist 408. This causes the unfavorable fence structure remained in the via hole 411 without being removed.

Typical interlayer film that may possibly cause such problem includes an insulating film containing nitrogen [silicon oxynitride (SiON), silicon carbonitride (SiCN) or the like] and a low-dielectric constant film (low-k film) having a pore in the film. The insulating film containing nitrogen may possibility employed for an etch stop film in the future (even in the advanced low-k insulating film configuration). In case of the low-k film containing the pore, amine existing in the clean room ambient atmosphere may possibly be taken in the pore, or amine/ammonia components taken during the cleaning process may possibly be remained.

Japanese Patent Laid-Open No. 2001-93,977 discloses the following technical feature related to a process for manufacturing a dual damascene structure. More specifically, Japanese Patent Laid-Open No. 2001-93,977 discloses that an organic insulating material, which is photosensitive to electron beam, is employed for an insulating film in a layer that covers the interconnect and the via hole, and an exposure process for a section corresponding to the via and an exposure process for a section corresponding to the interconnect are subsequently carried out and then a developing process is carried out to form concave sections corresponding to the interconnect and the via hole.

In addition, background technologies related to the present invention include technologies disclosed in Japanese Patent Laid-Open No. 2003-309,172, Japanese Patent Laid-Open No. 2005-10,633 and, Japanese Patent Laid-Open No. 2006-133,315.

In the mean time, the process described in Japanese Patent Laid-Open No. 2001-93,977 utilizes a photosensitive (to electron beam) organic insulating material for an interlayer film, and energy of electron beam is controlled to provide a controlled exposing depth as being equivalent to the via depth or equivalent to the interconnect. Therefore, the organic insulating material employed in such technology should exhibit characteristics required for adopting to the interlayer insulating film, and thus it is more difficult to form finer pattern, as compared with the use of the resist.

In addition, while the interconnect trench having a depth equivalent to about a half of the thickness of the film of the organic insulating material is required to be formed by the exposure process with higher controllability in the operation for forming interconnect trenches, the photo-sensitivity of the resist along the thickness direction cannot be drastically changed, and thus it is difficult to form the interconnect trench with higher controllability, irrespective of the thickness of the interconnect pattern or positions of the interconnects.

Further, while the dielectric constant of the interlayer insulating film is generally reduced as the size of the device is reduced, a compatibility of such reduced dielectric constant with a desired photosensitivity is difficult.

### SUMMARY

According to one aspect of the present invention, there is provided a process for manufacturing a semiconductor device, including: forming an etching-target film over a substrate; forming a concave section on the etching-target film; forming a chemically amplified resist film over the etching-target film; exposing and developing the chemically amplified resist film to pattern thereof, forming an opening therein, at least a portion of an inner wall of the concave section being exposed through the opening; and etching the etching-target film through a mask of the patterned chemically amplified resist film to form an interconnect trench, wherein the exposing and developing the chemically amplified resist film includes exposing a region for forming the concave section to light, and also includes exposing a region for forming the interconnect trench to light.

In the process for manufacturing the semiconductor device, the operation of exposing the region for forming the concave section to light and the operation of exposing the region for forming the interconnect trench to light are included in the operation for exposing and developing the chemically amplified resist film to form the opening after forming the opening. More specifically, even if the chemically amplified resist film is buried in the concave section after the concave section is formed, the additional exposure to light is conducted for the region for forming the concave section again, and therefore the concave section is exposed with sufficient amount of light. This allows removing the exposed region in the concave section with a liquid developer, exposing at least a portion of the inner wall of the concave section, so that an interconnect trench of a desired configuration can be obtained. According to the process for manufacturing the semiconductor device, a generation of a resist poisoning is inhibited, achieving a manufacture of a semiconductor device that exhibits higher reliability.

According to the present invention, a process for manufacturing a semiconductor device that exhibits higher reliability and provides an inhibition of a generation of a resist poisoning can be achieved.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1A to FIG. 1C are cross-sectional views, illustrating a process for manufacturing a semiconductor device according to first embodiment of the present invention;

FIG. 2A to FIG. 2C are cross-sectional views, illustrating the process for manufacturing a semiconductor device according to first embodiment of the present invention;

FIG. 3A is a cross-sectional view illustrating manufacturing process of the semiconductor device according to first embodiment of the present invention, and FIG. 3B is a plan view thereof;

FIG. 4A is a SEM image of a plan view of a semiconductor device manufactured by the process for manufacturing the semiconductor device in the present embodiment, and FIG. 4B is SEM image of a plan view of a conventional semiconductor device;

FIGS. 5A Lo 5C are cross-sectional views, illustrating a process for manufacturing a semiconductor device according to second embodiment of the present invention;

FIGS. 6A and 6B are cross-sectional views, illustrating the process for manufacturing a semiconductor device according to second embodiment of the present invention;

FIGS. 7A to 7C are cross-sectional views, illustrating a conventional process for manufacturing a semiconductor device; and

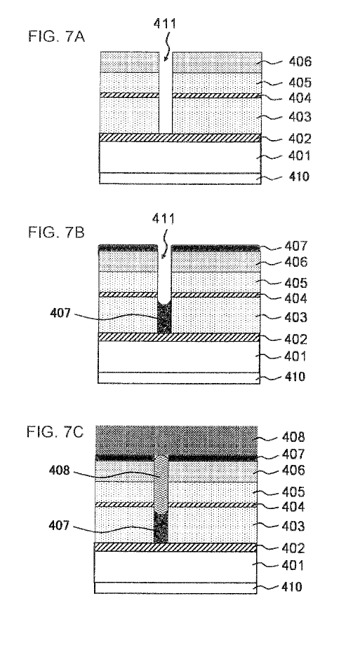

FIGS. 8A and 8B are cross-sectional views, illustrating a conventional process for manufacturing a semiconductor device.

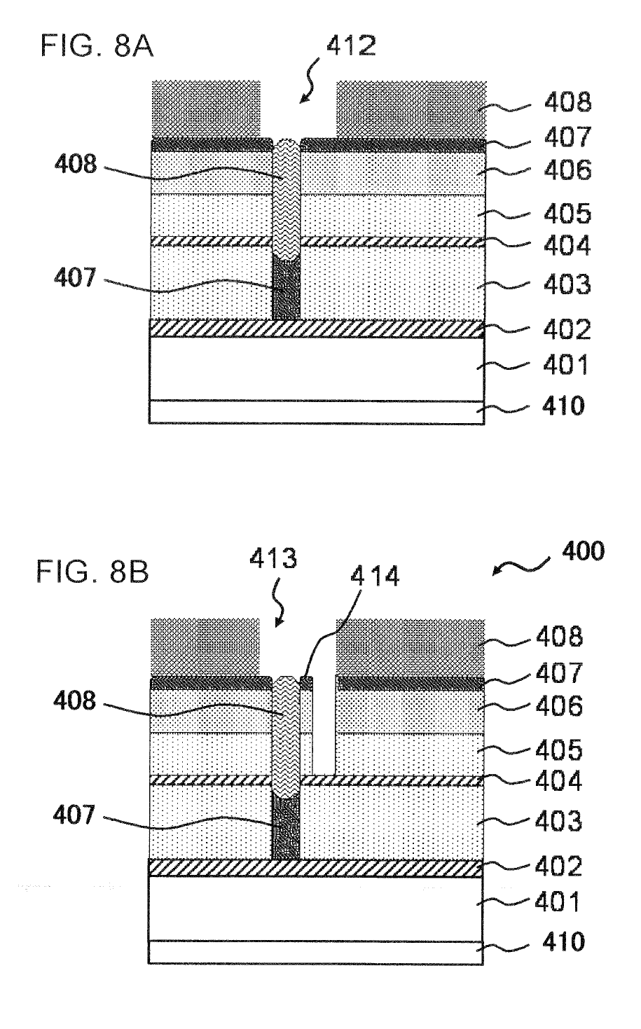

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Preferable embodiments for processes for manufacturing semiconductor devices according to the present invention will be described in detail as follows, in reference to the annexed figures. In all figures, an identical numeral is assigned to an element commonly appeared in the figures, and the detailed description thereof will not be repeated.

### First Embodiment

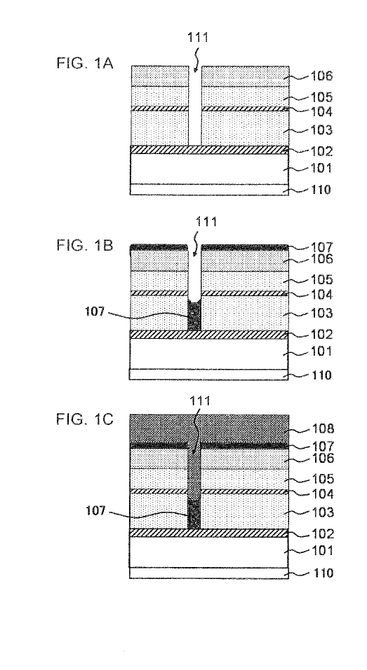

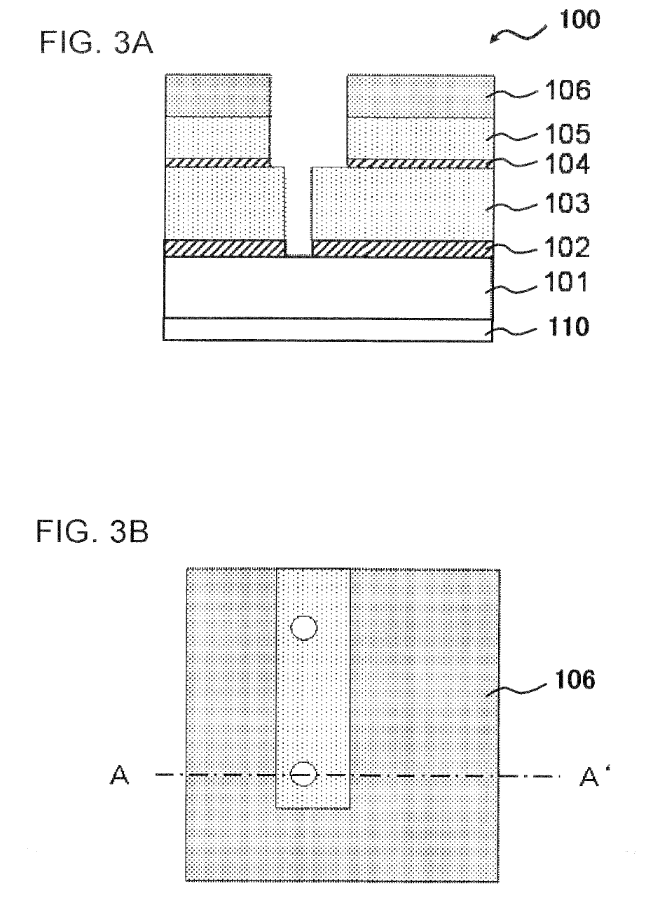

The present embodiment relates to a dual damascene process by a via-first process using a chemically amplified resist composition. FIG. 1A to FIG. 3A are cross-sectional views, illustrating a process for manufacturing a semiconductor device according to first embodiment of the present invention FIG. 3A is a cross-sectional view along line A-A′ appeared in FIG. 3B.

First of all, an underlying interconnect layer 101, a first etch stop film 102, a first interlayer insulating film 103, a second etch stop film 104, a second interlayer insulating film 105, and a third interlayer insulating film 106 are deposited in this order on a semiconductor substrate 110. Then, a via hole 111 is formed through the third interlayer insulating film 106, the second interlayer insulating film 105, the second etch stop film 104 and the first interlayer insulating film 103 by employing a lithographic technology for conducting an exposure process through a masking for forming vias and a processing technique (dry etching or the like) (FIG. 1A).

Subsequently, an anti-reflection film 107 is formed on the third interlayer insulating film 106 and the first etch stop film 102 (FIG. 1B). In this case, a portion of the section within the via hole 111 is filled with the anti-reflection film 107.

Subsequently, a chemically amplified resist 108 is applied on the anti-reflection film 107 (FIG. 1C).

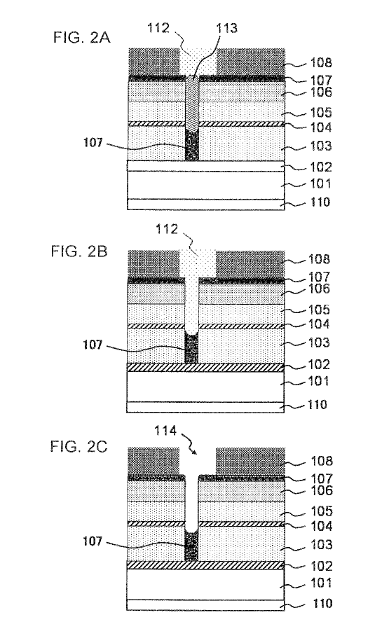

Then, the chemically amplified resist 108 is exposed to light by employing a mask for forming interconnect trenches that is coupled to the via hole 111. This allows a region 112 corresponding to the interconnect trench pattern being exposed to light (FIG. 2A). In such case, if the second etch stop film 104, the second interlayer insulating film 105, the third interlayer insulating film 106 and the like contain amine component, the region of the chemically amplified resist 108 that exhibits deteriorated photo-sensibility is formed by causing a neutralization reaction with acid generated in the chemically amplified resist 108 during the exposure process. More specifically, a region 113 within the via hole 111 where the chemically amplified resist 108 is in contact with the etching-target film is the region which is not sufficiently exposed.

Subsequently, the exposure process is conducted by employing again the mask for forming via employed in the processing of FIG. 1A to expose the section of the via hole 111 to expose the section of the via hole 111 to light, allowing the region 113 corresponding to the via pattern to be sufficiently exposed to light (FIG. 2B).

Then, the development process is conducted to remove the regions exposed to light, or namely the region 112 and the region 113, with a developing solution. This allows forming a recessed section having the inner wall of the via hole 111 at least partially exposed, or namely a trench 114, as shown in FIG. 2C.

Subsequently, a stripping operation is conducted to remove the anti-reflection film 107, and then to remove the third interlayer insulating film 106, the second interlayer insulating film 105 and the second etch stop film 104 by an etching process, so that the semiconductor device 100 having a trench structure corresponding to a dual damascene interconnect can be achieved (FIGS. 3A, 3B).

Light sources available for the lithography of the chemically amplified resist 108 includes, for example, krypton-fluoride (KrF) excimer-laser, argon-fluoride (ArF) excimer-laser, fluorine (F₂) excimer-laser, extreme ultraviolet (EUV), electron beam (EB) and the like.

The third interlayer insulating film 106 may be, for example, silicon dioxide (SiO₂) film, silicon oxycarbide (SiOC) film, silicon carbide (SiC) film, silicon carbonitride (SiCN) film and the like. Further, a low dielectric constant film composed of a low dielectric constant material, such as SiO₂ film, hydrogen silsesquioxane (HSQ) film, methyl silsesquioxane (MSQ) film, methylated hydrogen silsesquioxane (MHSQ) film, ladder hydrogenated siloxane film, SiLK (trademark) film, silicon oxyfluoride (SiOF) film, SiOC film, silicon oxynitride (SiON) film, BCB (benz cyclobutene) film and the like, may be employed for the second interlayer insulating film 105 and the first interlayer insulating film 103. While the use of the low dielectric constant film for the first interlayer insulating film 103 reduces the density of the film as compared with the SiO₂ film and provides easy absorption of an organic base such as amine compound and the like, the advantageous effect obtainable by employing the chemically amplified resist 108 is more preferably exhibited, and a sensibility and a resolution of the patterned resist can be preferably ensured.

The second etch stop film 104 and the first etch stop film 102 may be composed of, for example, SiC film, silicon nitride (SiN) film, SiON film or SiCN film. A use of a nitride film for the second etch stop film 104 or the first etch stop film 102 allows an easy penetration of a base component such as amine compound and the like in the second interlayer insulating film 105 or the first interlayer insulating film 103, and an additional use of the chemically amplified resist 108 in such case of employing these films further preferably achieve the effect of salt contained in the chemically amplified resist 108. Further, the chemically amplified resist 108 may be more preferably employed in the operation for forming a patterned resist on the insulating film having a concave section for forming the interconnect trench or the via. Further, the presence of the second etch stop film 104 is not necessarily required, depending on the control of the conditions for the etching process.

Advantageous effects obtainable by employing the process for manufacturing the semiconductor device of the present embodiment will be described. In the process for manufacturing the semiconductor device 100, the operation for forming the trench 114 after the via hole 111 is formed includes the operation for exposing the region for forming the via hole 111 to light and the operation for exposing the region for forming the interconnect trench. More specifically, even if chemically amplified resist 108 is buried in the via hole 111 after the via hole 111 is formed, then the region for forming of via hole 111 is exposed to light again, so that the inside of the via hole 111 is fully exposed to light. This allows removing the regions in via hole 111 exposed to light, or namely the region 112 and the region 113, with a developing solution, exposing at least a portion of the inner wall of the via hole 111 to obtain the trench 114 having a desired structure. According to the process for manufacturing the semiconductor device 100, a generation of a resist poisoning is inhibited, achieving a process for manufacturing the semiconductor device that exhibits higher reliability.

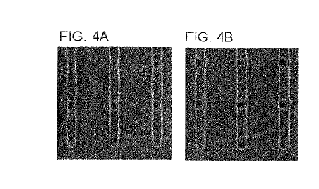

FIG. 4A is an image of a scanning electron microscope (SEM) of plan view of a semiconductor device 100 manufactured by the process for manufacturing the semiconductor device in the present embodiment, and FIG. 4B is SEM image of a plan view of a conventional semiconductor device. The width of the patterned interconnect appeared in FIGS. 4A and 4B is about 0.1 μm. In the comparison of FIG. 4A and FIG. 4B, it is particularly considerable that the aperture of the semiconductor device 100 in the via hole 111 of the interconnect trench 114 in the side of the tip is larger than the aperture of the conventional semiconductor device. More specifically, it is shown that a generation of resist poisoning can be prevented by employing the process for manufacturing the semiconductor device of the present embodiment.

### Second Embodiment

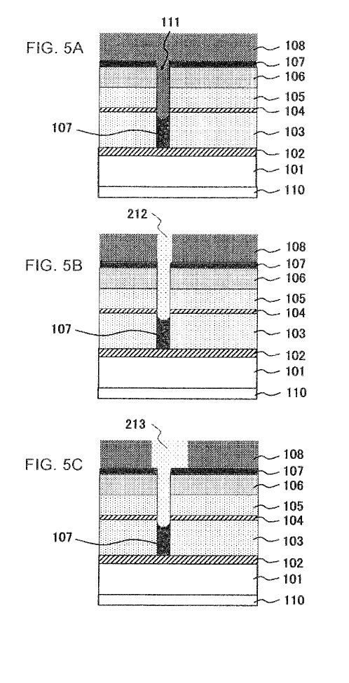

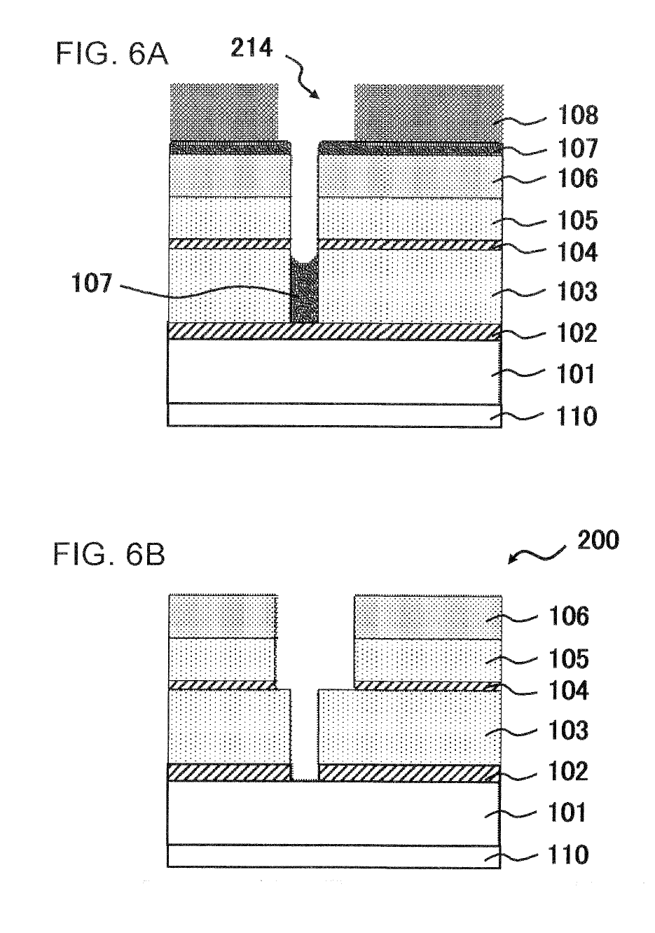

The interconnect structure shown in FIG. 3A may alternatively be manufactured by so called trench-first process, which is a type of the dual damascene processes. An interconnect structure formed by a trench-first process will be described as follows, in reference to FIGS. 5A to 5C and FIGS. 6A and 6B. In the present embodiment, an identical numeral is assigned to an element commonly appeared in the previous embodiment, and the detailed description thereof will not be repeated.

FIGS. 5A to 5C and FIGS. 6A and 6B are cross-sectional views, illustrating a process for manufacturing a semiconductor device according to second embodiment of the present invention.

A device shown in FIG. 5A has the same structure as shown in FIG. 1C. First of all, similarly as in first embodiment, a structure having a via hole 111 having an anti-reflection film 107 and a chemically amplified resist 108 sequentially applied thereon can be obtained.

Next, the exposure process is conducted by employing again the mask for forming via employed in the processing of FIG. 1A to expose the section of the via hole 111 to expose the section of the via hole 111 to light, allowing the region 212 corresponding to the via pattern to be sufficiently exposed to light (FIG. 5B).

Then, the chemically amplified resist 108 is exposed to light by employing a mask for forming interconnect trenches that is coupled to the via hole 111 to expose a region 213 corresponding to the interconnect trench pattern to light (FIG. 5C).

Then, the development process is conducted to remove the regions exposed to light, or namely the region 212 and the region 213, with a developing solution. This allows forming a recessed section having the inner wall of the via hole 111 at least partially exposed, or namely a trench 214, as shown in FIG. 6A.

A device shown in FIG. 6A has the same structure as shown in FIG. 2C, the semiconductor device 200 having the trench structure corresponding to the dual damascene interconnect can be achieved, similarly as in first embodiment (FIG. 6B).

In the present embodiment, the process for manufacturing the semiconductor device configured to be suitable for preventing a generation of a resist poisoning is achieved. Other advantageous effects of the present embodiment are similar to that of the above-described embodiment.

The semiconductor device and process for manufacturing the semiconductor device according to the present invention are not limited to the above-described embodiments, and various modifications are also available. While the configuration of the inner wall of the via hole being partially exposed by the exposure process employing the mask for forming via is disclosed in the above-described embodiments, the entire surface of the inner wall or the bottom surface of the via hole may be exposed. Further, the exposures to the light for the region for forming the via hole may alternatively be conducted in an arbitrary cycles. The mask for forming via may also be employed in the exposure process for the region for forming the via hole. Further, after exposing the region for forming the via hole to light, the region for forming the interconnect trench is exposed to light, and then the region for forming the via hole may be further exposed to light.

It is apparent that the present invention is not limited to the above embodiment, and may be modified and changed without departing from the scope and spirit of the invention.

What is claimed is:

1. A process for manufacturing a semiconductor device, including:
forming an etching-target film over a substrate;
forming a concave section over said etching-target film;
forming a chemically amplified resist film over said etching-target film;
exposing and developing said chemically amplified resist film to pattern thereof, forming an opening therein, at least a portion of an inner wall of said concave section being exposed through said opening; and
etching said etching-target film through a mask of said patterned chemically amplified resist film to form an interconnect trench,
wherein said exposing and developing said chemically amplified resist film includes exposing a region for forming said concave section to light, and also includes exposing a region for forming said interconnect trench to light.

2. The process for manufacturing the semiconductor device as set forth in claim 1, wherein two or more of said exposing the region for forming said concave section to light are conducted.

3. The process for manufacturing the semiconductor device as set forth in claim 2, wherein said exposing the region for forming said concave section to light is conducted after said exposing the region for forming said interconnect trench to light.

4. The process for manufacturing the semiconductor device as set forth in claim 2, wherein said exposing the region for forming said concave section to light is conducted before said exposing the region for forming said interconnect trench to light.
